(19) United States
(12) Patent Application Publication
(10) Pub. No.: US 2014/0313680 A1
(43) Pub. Date: Oct. 23, 2014

(54) SHIELD APPARATUS FOR ELECTRONIC DEVICE

(71) Applicant: Samsung Electronics Co., Ltd., Gyeonggi-do (KR)

(72) Inventors: Kwang-Min KIL, Gyeonggi-do (KR); Jae-Kyu LEE, Gyeonggi-do (KR)

(73) Assignee: Samsung Electronics Co., Ltd., Gyeonggi-do (KR)

(21) Appl. No.: 14/254,295

(22) Filed: Apr. 16, 2014

(30) Foreign Application Priority Data
Apr. 23, 2013 (KR) 10-2013-0044750

(51) Int. Cl. H05K 9/00

(52) U.S. Cl. CPC H05K 9/0024
USPC 361/752

(57) ABSTRACT

A shield apparatus for an electronic device includes: an electronic device case; a printed circuit board; a shield member mounted on a location of the printed circuit board; and at least one shield unit provided on the shield member to contact the electronic device case and be resiliently pressed by the electronic device case such that the shield member is coupled with the electronic device case.

### CROSS RELATED APPLICATION

This application claims the priority under 35 U.S.C. §119(a) to Korean Application Serial No. 10-2013-0044750, which was filed in the Korean Intellectual Property Office on Apr. 23, 2013, the entire content of which is hereby incorporated by reference in its entirety.

### BACKGROUND

1. Technical Field

The present disclosure relates to a shield apparatus for an electronic device, and more particularly, to a shield apparatus for an electronic device which includes at least one shield unit.

2. Description of the Related Art

In general, while electromagnetic waves are useful in wireless communications or radars, they may badly influence an operation of an electronic device, which is called an electromagnetic interference (EMI) phenomenon. The electromagnetic interference phenomenon generates noise in an electronic device, and can also act as a harmful element to a human body as well.

Thus, electronic components installed on a printed circuit board installed within an electronic device are typically covered by a shield member so that an electromagnetic interference phenomenon can be interrupted and contained within the shield member. Accordingly, electromagnetic waves cannot influence operations of the electronic device and other electronic devices. A shield member according to such an application typically has a lower end having an opened box shape to encase and cover the electronic components.

A shield member (shield can) of a portable terminal is disclosed in Unexamined Korean Patent Publication No. 10-2009-036465 (published on Apr. 14, 2009).

As shown in FIG. 1, the shield apparatus 1 according to the related art includes a printed circuit board 2 having a plurality of electronic components 2a, a plurality of fixing clips 3 provided on the printed circuit board 2, and a shield member 4 coupled and fixed to the fixing clips 3.

As shown in FIG. 2, the shield member 4 generally includes a shield frame 4a and a shield cover 4b coupled to the shield frame 4a.

However, as shown in FIG. 2, since the shield apparatus 1 according to the related art has a dual structure in which a shield cover 4b is coupled to an upper portion of the shield frame 4a, a thickness of the shield apparatus 1 is increased. Accordingly, a mounting space is necessary in the electronic device 5 to accommodate the shield apparatus 1, and thus the increased size of the shield apparatus becomes a factor hindering the miniaturization and slimness of the electronic device 5. Further, the number of assembly processes and manufacturing costs of a product also increase due to the shield assembly being made of more than a single component.

In order to solve the problem, as shown in FIG. 3, a partition 30 for shielding a component 20a of a printed circuit board 20 is formed in a metal bracket 10 instead of a conventional shield member. That is, the partition structure of the metal bracket 10 includes a conductive gasket (adhesive) 40 in the partition 30 such that the partition 30 is mounted on the printed circuit board 20 to contact the printed circuit board 20.

However, the partition structure of the metal bracket cannot perfectly perform a shielding function due to deviation of conductivities of the conductive gasket 40 and deviation of resistances of the metal bracket 10, thus lowering a shielding force of the partition structure. Thus, since a shield cover 50 for shielding a component of the printed circuit board 20 should be separately 30 provided to increase a shielding force of a product, a thickness, the number of assembly processes, and manufacturing costs of the product increase.

Here, the deviation of conductivities refers to a degree by which a current flowing through the gasket deviates from a predetermined reference value. Further, the deviation of resistances refers to a difference between a resistance value measured in the metal bracket and a standard resistance value of the metal bracket.

In addition, since the partition is integrally formed with the metal bracket in the partition structure of the metal bracket according to the related art, a metal bracket should be manufactured again together with a partition to correspond to a new location of a component to be shielded whenever the location of the component is changed, which increases manufacturing costs of the product and makes it difficult to standardize the component in order to commonly use the product.

Thus, a shield apparatus having a single structure instead of a conventional dual structure of a shield frame and a shield cover is required to overcome the disadvantages of the conventional shield member.

### SUMMARY

The present invention provides a shield apparatus for an electronic device which includes at least one shield unit configured to contact an electronic device case and be pressed by the electronic device case such that the electronic device case can be used as a shield cover instead of a conventional shield cover, thereby improving a shield force and an assembly efficiency of a product, reducing manufacturing costs of the product, excluding a separate mounting space to reduce the thickness of the product, and make the electronic device small and slim.

The present invention also provides a shield apparatus for an electronic device which includes at least one shield finger or shield gasket configured to contact an electronic device case and be resiliently pressed by the electronic device case and to have a single structure instead of a dual structure of a conventional shield frame and a shield cover, thereby further reducing the thickness of the product, and further improving a shielding function and an assembly efficiency of a product.

The present invention also provides a shield apparatus for an electronic device which includes a shield member configured to vary to correspond to a component mounted to a printed circuit board, thereby making it unnecessary to manufacture a customized product to adapt to a particular installation location of a component provided in an electronic device in accordance with the related art, thereby reducing manufacturing costs of a product, and shielding different components provided in the same electronic device according to locations and shapes thereof to commonly use the product.

In order to solve the above-described problems, there is provided a shield apparatus for an electronic device, including: an electronic device case; a printed circuit board; a shield member mounted on a location of the printed circuit board to be shielded; and at least one shield unit provided on the shield member to contact the electronic device case and be resiliently pressed by the electronic device case such that the shield member is coupled with the electronic device case.

In accordance with another aspect of the present invention, there is provided a shield apparatus for an electronic device, including: a printed circuit board; a shield member mounted on a location of the printed circuit board to be shielded; an electronic device case provided to cover the shield member; and at least one shield finger provided on the shield member to contact the electronic device case and be resiliently pressed by the electronic device case such that the shield member is coupled with the electronic device case.

In accordance with still another aspect of the present invention, there is provided a shield apparatus for an electronic device, including: a printed circuit board to which a plurality of components are mounted; a shield member mounted on a location of the printed circuit board to shield at least one of the plurality of components; an electronic device case provided to cover the shield member; and a shield gasket provided on an upper surface of the shield member to attach the electronic device case to the shield member.

### BRIEF DESCRIPTION OF THE DRAWINGS

The above and other aspects, features, and advantages of the present invention will be more apparent from the following detailed description taken in conjunction with the accompanying drawings, in which:

FIG. 1 is an exploded perspective view showing a configuration of a shield apparatus according to the related art;

FIG. 2 is a side sectional view showing the configuration of the shield apparatus according to the related art;

FIG. 3 is a side sectional view depicting the shield apparatus according to the related art which includes a partition in a metal bracket;

FIG. 4 is a perspective view showing a configuration of a shield apparatus for an electronic device according to a first embodiment of the present invention;

FIG. 5 is a side view showing the configuration of the shield apparatus for an electronic device according to the first embodiment of the present invention;

FIG. 6 is a perspective view showing a coupled state of the shield apparatus for an electronic device according to the first embodiment of the present invention;

FIG. 7 is a side view showing an operational state of the shield apparatus for an electronic device according to the first embodiment of the present invention;

FIG. 8 is a perspective view showing a configuration of a shield apparatus for an electronic device according to a second embodiment of the present invention;

FIG. 9 is a side view showing a configuration of the shield apparatus for an electronic device according to the second embodiment of the present invention; and

FIG. 10 is a side view showing an operational state of the shield apparatus for an electronic device according to the second embodiment of the present invention.

### DETAILED DESCRIPTION

Hereinafter, exemplary embodiments of the present invention will be described in detail with reference to the accompanying drawings to assist in a comprehensive understanding of exemplary embodiments of the invention as defined by the claims and their equivalents. In the following description, detailed descriptions of well-known functions or configurations will be omitted since they would unnecessarily obscure the subject matters of the present invention by a person of ordinary skill in the art with unnecessary detail of the well-known functions and structures. Also, the terms used herein are defined according to the functions of the present invention. Thus, the terms may vary depending on users' or operators' intentions or practices. Therefore, the terms used herein should be understood based on the descriptions made herein in view of the ordinary level of skill in the art. The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention are provided for illustration purpose only and not for the purpose of limiting the invention as defined by the appended claims and their equivalents.

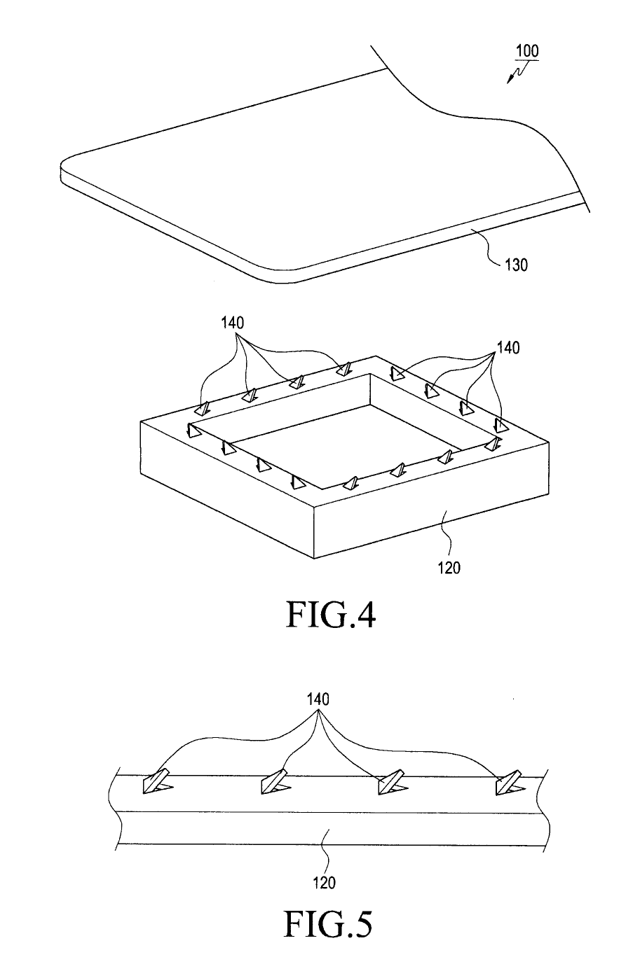

FIGS. 4 and 5 are views showing a configuration of a shield apparatus 100 of an electronic device according to a first embodiment of the present invention.

The configuration of the shield apparatus 100 will be described with reference to FIGS. 4 and 5. The shield apparatus 100 includes a printed circuit board 110 provided in the electronic device (not shown), a shield member 120 provided in the printed circuit board 110, an electronic device case 130, and one or more shield units. A shield member 120, which will be described below, is provided on a surface of the printed circuit board 110. The shield member 120 is provided on an upper surface of the printed circuit board 110 to interrupt an electromagnetic interference (EMI) phenomenon generated by components 110a provided in the printed circuit board 110. As shown in FIG. 7, the electronic device case 130 covers an upper portion of the shield member to shield the components 110a. The shield units are provided on the shield member 120 to be pressed by the electronic device case 130 while contacting the electronic device case 130.

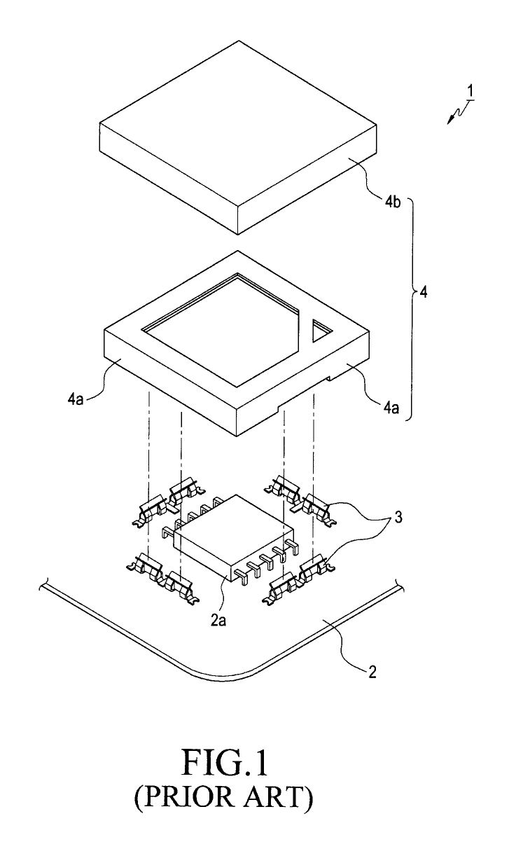

The shield units include shield fingers 140 obtained by cutting portions of upper surfaces of the electronic device case 130 and separating the cut portions to protrude upward. That is, the shield fingers 140 are resiliently pressed while contacting the electronic device case 130, whereby the electronic device case 130 directly performs a shield cover function instead of the conventional shield cover 4b (see FIG. 1), eliminating a shield cover space provided in the electronic device to reduce a thickness of a product, and making the electronic device small-sized and slim. Further, a shielding force and an assembly efficiency of the product can be improved and manufacturing costs of the product can be reduced. As shown in FIG. 4, the electronic device case 130 preferably includes one of a front case, a rear case, a metal bracket, a housing, a plastic bracket, and the like.

The shield member 120 is provided on a surface of the printed circuit board 110 to vary so as to correspond to a location of the component 110a mounted to the printed circuit board 110. That is, the shield member 120 is mounted to a portion of the printed circuit board in a surface mounted device (SMD) type.

In this way, the shield member 120 is mounted to an installation location and a shape of the component 110a provided in the electronic device. Further, the shield member 120 need not be manufactured to accommodate a particular location of the component whenever the location of the component 2a (see FIG. 1) is changed, and manufacturing costs of the product can be reduced. In addition, since the shield member 120 may correspond to the location and shape of the components 110a of the same electronic device, it can be commonly used for shielding a variety of components.

In addition, the shield member 120 preferably includes a support frame 125 to support the shield fingers 140. That is, a lower surface of the shield member 120 is soldered to a surface of the printed circuit board 110, and the shield fingers 140 are provided on an upper surface 125 of the shield member 120. Thus, the shield member 120 preferably includes a rib or a support frame which may be the front, back and side walls 127 of the shield member 120, the sidewalls connected between the front and back walls.

The shield member 120 preferably may be a tetragonal shape, a lozenge (oval) shape, a rectangular shape, an L shape, or a lightning (zigzag) shape. Thus the shield member 120 may have a shape other than the shape shown and described herein.

The shield fingers 140 are preferably clips, springs, or bosses. The shield fingers 140 may have shapes other than the clips, the springs, or the bosses shown and described herein.

The shield fingers 140 are preferably provided on an upper surface 125 of the shield member 120 and according to the shape of the shield member 120 as well.

Here, an assembly process of the shield fingers 140 will be described in more detail below.

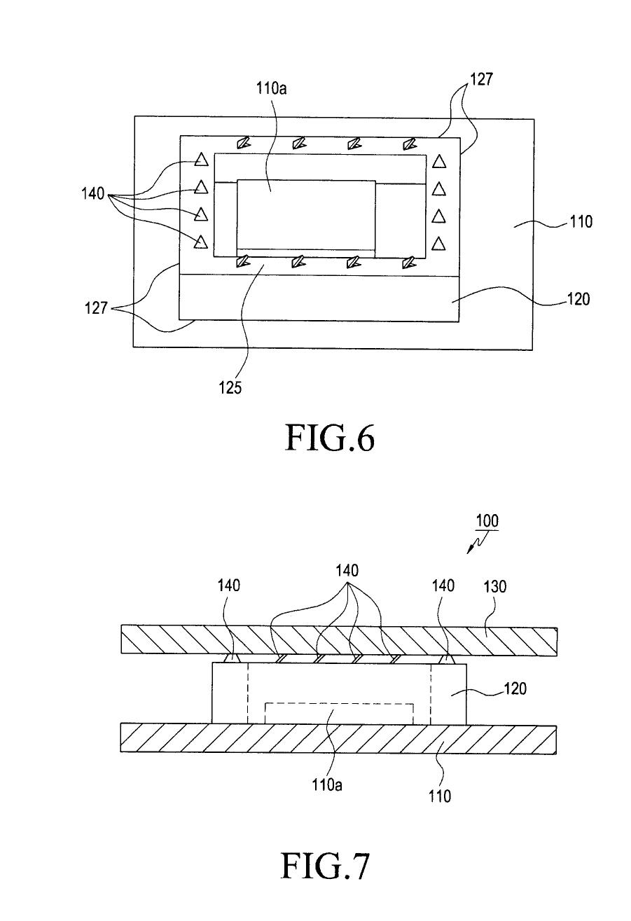

First, FIG. 6 is a perspective view showing a coupled state of the shield fingers 140 according to the first embodiment of the present invention. FIG. 7 is a side view showing an operational state of the shield fingers 140 according to the first embodiment of the present invention.

First, as in FIGS. 6 and 7, the shield member 120 is mounted to a portion 30 of the printed circuit board 110, which is to be shielded, in an surface mount device (SMD) type through soldering. The shield member 120 is mounted around an outer circumference of the components 110a included on the surface of the printed circuit board 110. Then, the shield member 120 is variably mounted to correspond to installation locations and shapes of the components 110a of the printed circuit board 110.

In this state, the electronic case 130 is coupled to an upper portion of the shield member 120 using shield fingers 140 and covers the components 110a provided in an interior of the shield member 120 at the same time

When the electronic case 130 is resiliently pressed onto the shield member 120, then, the shield fingers 140 provided on the shield member 120 contact the electronic device case 130 to be resiliently pressed, and cover the shield member 120 at the same time.

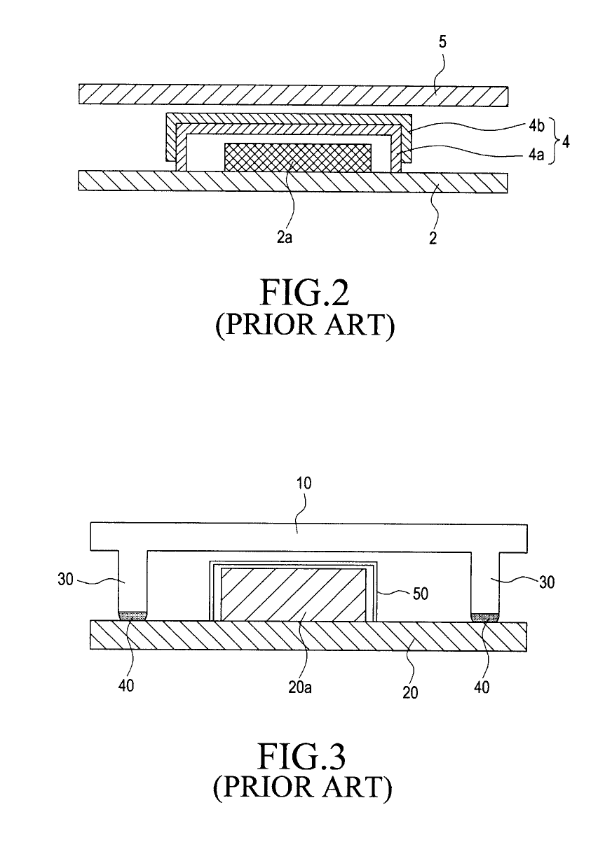

In this way, since the shield apparatus 1 (see FIG. 1) according to the related art has a dual structure in which the electronic device case is not used as a shield cover but the shield cover 4b (see FIG. 2) is coupled to an upper portion of the shield frame 4a (see FIG. 2), thereby requiring an extra component to cover the shield from, therefore a thickness of the shield apparatus 1 increases and accordingly, a mounting space for mounting the shield cover within the electronic device 5 (see FIG. 2) is separately required, making it difficult to miniaturize and slim the electronic device and increasing the number of assembly processes and manufacturing costs of the product.

In order to overcome the disadvantage, the shield fingers 140 of the present invention directly contact the electronic device case 130 without using a separate shield cover and the shield fingers are resiliently pressed between the shield member 120 and the electronic case 130 to shield the components 110a, making it possible to reduce a thickness of a product as the electronic case 130 is coupled to the shield member and provides the cover of the shield member 120 and thus the conventional shield cover utilizing an extra component is eliminated, and accordingly, to miniaturize and slim the electronic device. Thus, a shielding force and an assembly efficiency of a product can be improved and manufacturing costs of the product can be reduced.

Further, in the conventional shield apparatus including the metal frame 10 (see FIG. 3) with which the partition 30 (see FIG. 3) is integrally formed, since a metal bracket should be manufactured together with a partition to correspond to a location of a component to be shielded whenever a location of the component is changed in the electronic device, manufacturing costs of the product increase and it is difficult to commonly use the product.

Thus, in order to overcome the disadvantage, since the shield member 120 (see FIG. 7) and the shield fingers 140 (see FIG. 7) are mounted in positions which may vary according to the locations and shapes of the shielded components included in the same electronic device, a new shield member does not need to be manufactured to correspond to a location of a component to be shielded whenever the location of the component is changed in the same electronic device. In other words, because the electronic case 130 serves as the cover of shield member 120, a separate cover or a specialized shape of shield member 120 is not needed. By simply varying the location and positions of shield fingers 140 to align with the electronic case 130, the shield member 120 can be coupled with the electronic case 130. Accordingly, manufacturing costs of the product can be reduced. In addition, even if a location and a shape of a component are different in the same electronic device, the shield member can be mounted to vary according to the location and shape of the component and the product can be commonly used. Further, costs for additional manufacturing and verifying of the product can be reduced.

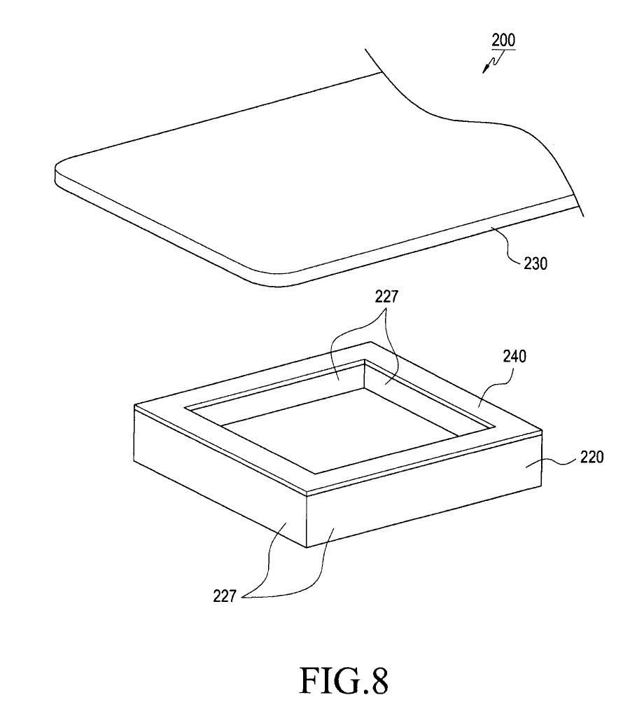

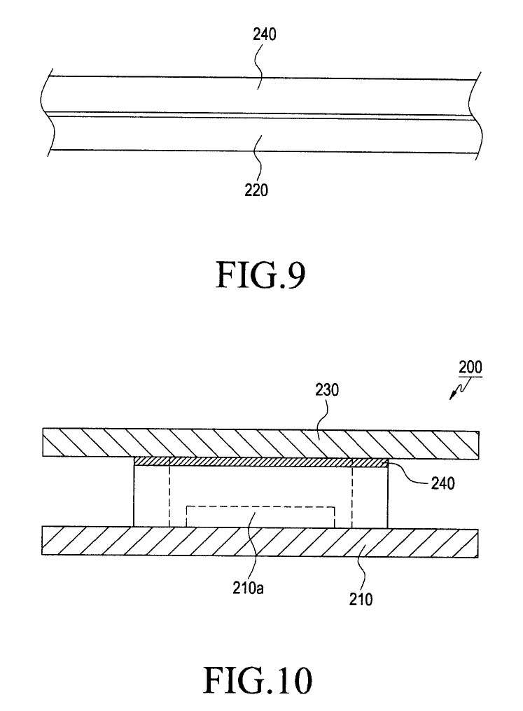

FIGS. 8 and 9 are views showing a configuration of a shield apparatus 200 of an electronic device according to a second embodiment of the present invention.

Hereinafter, a configuration of the shield apparatus 200 will be described with reference to FIGS. 8, 9 and 10. The shield apparatus 200 includes a printed circuit board 210 provided in the electronic device (not shown), a shield member 220 provided in the printed circuit board 210, an electronic device case 230, and a shield unit. A shield member 220, which will be described below, is provided on a surface of the printed circuit board 210. The shield member 220 is provided on an upper surface of the printed circuit board 210 to interrupt an electromagnetic interference (EMI) phenomenon generated by components 210a provided in the printed circuit board 210. The electronic device case 230 covers an upper portion of the shield member to shield the components 210a.

The shield unit includes a shield gasket applied to an upper end surface 225 of the shield member 220. That is, since the shield gasket 240 contacts the electronic device case 230 to be attached to the electronic device case 230, the electronic device case 230 directly functions as a shield cover instead of the conventional shield cover which utilizes a separate component. In other words, because the electronic case 230 serves as the cover of shield member 220, a separate cover or a specialized shape of shield member 220 is not needed. By simply including shield gasket 240 to contact with the electronic case 130, the shield member 220 can be coupled with the electronic case 230. Accordingly, since a space for a shield cover in the electronic device is not necessary, a thickness of a product can be reduced and the product can be miniaturized and slimmed. Further, a shielding force and an assembly efficiency of the product can be improved and manufacturing costs of the product can be reduced.

As shown in FIG. 8, the electronic device case 230 preferably includes one of a front case, a rear case, a metal bracket, a housing, a plastic bracket, and the like.

The shield member 220 is provided on a surface of the printed circuit board 210 to vary by location so as to correspond to a location of the component 210a mounted to the printed circuit board 210. That is, the shield member 220 can be mounted to a portion of the printed circuit board, which is to be shielded, in a surface mounted device (SMD) type.

In this way, the shield member 220 is mounted to an installation location and a shape of the component 210a provided in the electronic device. Further, the shield member 120 or 220 does not need to be modified or re-manufactured whenever the location of the conventional component 210a is changed, and manufacturing costs of the product can be reduced. In addition, since the shield member 220 may correspond to the location and shape of the components 210a of the same electronic device, it can be commonly used for a variety of printed circuit board 110 configurations.

In addition, the shield member 220 preferably includes a support frame to support the shield gasket 240 such that the shield gasket 240 can be applied. That is, a lower surface of the shield member 220 is soldered to a surface of the printed circuit board 110, and the shield gasket 240 is provided on an upper surface of the shield member 220. Thus, the shield member 220 preferably includes a rib or a support frame which may be the front, back and side walls 227 of the shield member 220 the sidewalls connected between the front and back walls.

The shield member 220 preferably has a tetragonal shape, a lozenge (oval) shape, a rectangular shape, an L shape, or a lightning (zigzag) shape. Here, the shield member 220 may have a shape other than the disclosed shapes.

The shield gasket 240 is preferably formed of one of rubber, sealant, silicon, cork, and adhesive. However, the shield gasket 240 may also be formed of a material other than rubber, sealant, silicon, cork, and adhesive as would be apparent to one skilled in the art.

The shield gasket 240 is provided on an upper surface of the shield member 220 according to the shape of the shield member 220.

Hereinafter, an assembly process of the shield gasket 240 will be described in more detail.

FIG. 8 is a perspective view showing a shield gasket 240 according to the present invention. FIG. 9 is a side view showing the shield gasket 240 according to the present invention. FIG. 10 is a side view showing an operational state of the shield gasket 240 according to the present invention.

First, as in FIGS. 8 and 9, the shield member 220 is mounted to a portion of the printed circuit board 210, which is to be shielded, in an SMD type through soldering. The shield member 220 is mounted around an outer circumference of the components 210a included in the printed circuit board 110. Then, the shield member 220 is variably mounted to correspond to installation locations and shapes of the components 210a of the printed circuit board 210. In this state, the electronic case 230 is coupled to an upper portion of the shield member 220 and covers the components 210a provided in an interior of the shield member 220 at the same time

Then, the shield fingers 240 provided on the shield member 220 contacts the electronic device case 230 to be resiliently pressed, and cover the shield member 220 at the same time.

In this way, the shield gasket 240 of the present invention directly contacts the electronic device case 230 without using a separate shield cover and is attached to the electronic device case 230 to cover the shield member 220, making it possible to reduce a thickness of a product as the conventional shield cover is eliminated, and accordingly, to miniaturize and slim the electronic device. Thus, a shielding force and an assembly efficiency of a product can be improved and manufacturing costs of the product can be reduced.

Further, in the conventional shield apparatus including the metal frame 10 (see FIG. 3) with which the partition 30 (see FIG. 3) is integrally formed, since a metal bracket should be manufactured again together with a partition to correspond to a location of a component to be shielded whenever a location of the component is changed in the electronic device, manufacturing costs of the product increase and it is difficult to commonly use the product.

Thus, in order to overcome the disadvantage, since the shield member 220 (see FIG. 7) and the shield gasket 240 are mounted to vary according to the locations and shapes of the shielded components included in the same electronic device, a new shield member 220 does not need to be modified during manufacture to correspond to a location of a component 210a to be shielded whenever the location of the component is changed in the same electronic device. Accordingly, manufacturing costs of the product can be reduced. In addition, even if a location and a shape of a component 210a are different in the same electronic device, the shield member can be mounted to vary according to the location and shape of the component and the product can be commonly used for various devices. Further, costs for additional manufacturing and verifying of the product can be reduced.

Moreover, since the shield apparatus for a metal bracket with which the conventional partition is integrally formed includes the conductive gasket 40 (see FIG. 3) in the partition 30 (see FIG. 3) to be bonded to the printed circuit board, a separate shield cover 50 (see FIG. 3) is provided to prevent lowering of a shielding force generated by a deviation in conductivities of the conductive gasket 40 and deviation in resistances of the metal bracket 10 (see FIG. 3).

Thus, since the shield gasket 240 according to the present invention is directly attached to the electronic device case 230 without using a separate shield cover 4a (see FIG. 1) to cover the shield member 220, deviation in conductivities of the conventional conductive gasket and deviation in resistances of the metal bracket can be prevented, and accordingly, a shielding force of the product can be improved.

Meanwhile, examples of electronic devices according to the embodiments of the present invention may include all information communication devices and multimedia devices such as portable multimedia players (PMPs), MP3 players, navigation systems, gaming devices, notebooks, advertising panels, TVs, digital broadcasting players, personal digital assistants (PDAs), and smart phones, including all mobile communication terminals as well as portable terminals operated based on communication protocols corresponding to various communication systems, and application devices thereof

The above-described shield apparatus for an electronic device according to the present invention is not limited to the embodiments and the drawings, but it is apparent to those skilled in the art to which the present invention pertains that the present invention can be variously substituted, modified, and changed without departing from the spirit and scope of the present invention as defined by the appended claims. Therefore, the scope of the invention is defined not by the detailed description of the invention but by the appended claims, and all differences within the scope will be construed as being included in the present invention.

What is claimed is:

1. A shield apparatus for an electronic device, comprising:
an electronic device case;
a printed circuit board;
a shield member mounted on a location of the printed circuit board to be shielded; and
at least one shield unit provided on the shield member to contact the electronic device case and be resiliently pressed by the electronic device case such that the shield member is coupled with the electronic device case.

2. The shield apparatus of claim 1, wherein the shield unit may be a shield finger or a shield gasket located on an upper surface of the shield member.

3. The shield apparatus of claim 1, wherein the shield member is provided to be mounted on a location of the printed circuit board that may vary so as to correspond to a location of a component mounted to the printed circuit board.

4. A shield apparatus for an electronic device, comprising:
a printed circuit board;
a shield member mounted on a location of the printed circuit board to be shielded;
an electronic device case provided to cover the shield member; and
at least one shield finger provided on the shield member to contact the electronic device case and be resiliently pressed by the electronic device case such that the shield member is coupled with the electronic device case.

5. The shield apparatus of claim 4, wherein the electronic device case comprises a front case, a rear case, a metal bracket, a housing, and a plastic bracket.

6. The shield apparatus of claim 4, wherein the shield member is provided to be mounted on a location of the printed circuit board that may vary so as to correspond to a location of a component mounted to the printed circuit board.

7. The shield apparatus of claim 4, wherein the shield member has a shape selected from one of a tetragonal shape, a lozenge shape, a rectangular shape, an L shape, or a zigzag shape.

8. The shield apparatus of claim 4, wherein the shield member comprises a support frame, the support frame having a front wall a back wall and two sidewalls connected there between for supporting an upper surface, wherein the shield finger is provided on the upper surface.

9. The shield apparatus of claim 4, wherein the shield finger comprises a component selected from one of a clip, a spring, and a boss.

10. The shield apparatus of claim 4, the shield finger is provided to correspond to a shape of the shield member for coupling the shield member to the electronic device case.

11. A shield apparatus for an electronic device, comprising:
a printed circuit board to which a plurality of components are mounted;
a shield member mounted on a location of the printed circuit board to shield at least one of the plurality of components;
an electronic device case provided to cover the shield member; and
a shield gasket provided on an upper surface of the shield member to attach the electronic device case to the shield member.

12. The shield apparatus of claim 11, wherein the electronic device case comprises a front case, a rear case, a metal bracket, a housing, and a plastic bracket.

13. The shield apparatus of claim 11, wherein the shield member is provided to be mounted on a location of the printed circuit board that may vary so as to correspond to a location of a component mounted to the printed circuit board.

14. The shield apparatus of claim 11, wherein the shield member has a shape selected from one of a tetragonal shape, a lozenge shape, a rectangular shape, an L shape, or a lightning shape.

15. The shield apparatus of claim 11, wherein the shield member comprises a support frame, the support frame having a front wall a back wall and two sidewalls connected there between for supporting an upper surface wherein a shield finger is provided on the upper surface.

16. The shield apparatus of claim 11, wherein the shield gasket is formed of a material selected from one of either rubber, sealant, silicon, cork, and adhesive.

17. The shield apparatus of claim 11, the shield gasket is provided to correspond to a shape of the shield member for coupling the shield member to the electronic device case.

18. The shield apparatus of claim 11, wherein the shield gasket may protrude from an upper surface of the shield member.

19. The shield apparatus of claim 11, wherein the shield gasket corresponds to the shape of the shield member.

20. The shield apparatus of claim 11, wherein the shield gasket is compressed between the shield member and the electronic device case.
